(19) United States
(12) Patent Application Publication
(10) Pub. No.: US 2014/0152348 A1
(43) Pub. Date: Jun. 5, 2014

(54) BICMOS CURRENT REFERENCE CIRCUIT

(71) Applicant: China Electronic Technology Corporation, 24th Research Institute, Chongqing City (CN)

(72) Inventors: Rong-Bin Hu, Chongqing City (CN); Gang-Yi Hu, Chongqing City (CN); Dong-Bing Fu, Chongqing City (CN); Yong-Lu Wang, Chongqing City (CN); Zheng-Ping Zhang, Chongqing City (CN); Can Zhu, Chongqing City (CN); Yu-Han Gao, Chongqing City (CN); Lei Zhang, Chongqing City (CN); Rong-Ke Ye, Chongqing City (CN)

(73) Assignee: China Electronic Technology Corporation, 24th Research Institute, Chongqing City (CN)

(21) Appl. No.: 14/115,630

(22) PCT Filed: Sep. 27, 2012
(86) PCT No.: PCT/CN12/82150

§ 371 Date: Nov. 4, 2013

(30) Foreign Application Priority Data
Sep. 19, 2012 (CN) 201210349381.5

(51) Int. Cl. H03K 3/01

(52) U.S. Cl. CPC H03K 3/01
USPC 327/108

(57) ABSTRACT

A BiCMOS current reference circuit includes a reference core, a startup circuit, and a reference current output circuit. The reference core contains a current mirror, a positive temperature coefficient current generator, and a negative temperature coefficient current generator. The current mirror generates matching branch current. The positive and negative temperature coefficient currents were added in certain proportion to generate a reference current with zero temperature coefficient at room temperature. The startup circuit starts the reference core at power-on. The reference current output circuit proportionably outputs reference current generated by the reference core. Compared with the conventional voltage reference, the circuit uses current conveying technique, so it won't be affected by DC voltage drops of power supply network, and it features low transmission loss, good matching, excellent temperature stability, small chip size and auto-startup at power-on. It's preferably suitable for applications where A/D and D/A converters require accurate reference signals.

### BACKGROUND OF THE INVENTION

1. Field of the Invention

The invention relates to a reference generation for analog and digital hybrid integrated circuit, particularly to a BiCMOS (Bipolar Complementary Metal Oxide Semiconductor) current reference circuit.

2. Description of Related Art

A conventional reference circuit usually has a complicated structure. The reference signals generated by the reference circuit are unstable, and even there might be some problems with circuit startup. So, it is not applicable for applications where very accurate reference signals are required.

FIG. 1 illustrates a conventional voltage reference generating circuit, which comprises bipolar transistors 111 and 112, resistors 113, 114 and 115, and an operational amplifier 110, which generates reference voltage at its output (VOUT).

Since the resistors 113, 114, 115 and the operational amplifier 110 form a feedback network, voltages at both input ends of the operational amplifier 110 are approximately the same. Resistances of the resistors 114 and 115 are designed as the same value (R2), so that currents flowing through the resistors 114 and 115, respectively, are current I. As voltages at both input ends are the same, there is:

V_{be1}=IR₁+V_{be2} (600)

wherein Vbe1 and Vbe2 are base-emitter junction voltages of the transistors 111 and 112, respectively. R1 is the resistance of the resistor 113. According to current-voltage relation of bipolar transistor, it can be further derived:

$${V}_{t} ln \frac{I}{{I}_{s 1}} = {IR}_{1} + {V}_{t} ln \frac{I}{{I}_{s 2}} \qquad ( 601 )$$

wherein Vt is a physical constant in direct proportion to absolute temperature, which is approximately 0.026V at room temperature. Is1 and Is2 are device constants in direct proportion to emitter sizes of transistors 111 and 112, respectively. Further settling Equation 601, there derives:

$$I = \frac{{V}_{t}}{{R}_{1}} ln M \qquad ( 602 )$$

wherein M is the ratio of emitter sizes of transistors 112 and 111. So, the output voltage of the operational amplifier 110 might be expressed as:

$$VOUT = {V}_{be 1} + \frac{{R}_{2} {V}_{t}}{{R}_{1}} ln M \qquad ( 603 )$$

wherein Vbel is a negative temperature coefficient and Vt is a positive temperature coefficient. By choosing proper values for R2, R1 and M, VOUT can be zero at a certain temperature, which is usually room temperature.

Said voltage reference circuit is subject to effects of offset voltage of the operational amplifier, and there is a big voltage loss when the reference voltage is transmitted to other circuit blocks through long distance transmission. Also, it tends to be affected by supply noise and DC voltage drop of the power supply network.

FIG. 2 illustrates a conventional current reference generator, which is made by adding two PMOSFETs 116 and 117, to the voltage reference generator in FIG. 1. The two PMOSFETs, which have the same size, constitute a pair of current mirrors. Iref is the reference current. Similarly, current I is calculated by applying expression of Vt to Equation 602:

$$I = \frac{KT}{{qR}_{1}} ln M \qquad ( 604 )$$

wherein K is Boltzmann constant, T is absolute temperature, q is the charge of electrons, and other parameters are as described before. Equation 604 shows current I is in direct proportion to absolute temperature. Iptat flowing through source-drain junction of PMOS transistor 116 is twice current I. Due to current mirror, current Iref is equal to Iptat. Therefore,

$${I}_{ref} = \frac{2 KT}{{qR}_{1}} ln M \qquad ( 605 )$$

wherein parameters are as described above. Equation 605 shows that Iref is in direct proportion to absolute temperature.

Said current reference circuit has such disadvantages as variation of reference current proportional to absolute temperature, complicated circuit (including operational amplifier) and large chip size.

FIG. 3 is a conventional current reference circuit, which has additional NMOS transistors 121, 122, 120 and resistor 123, compared to FIG. 2. Similarly, due to operational amplifier 110, currents going through resistor 114 and 115 are equal, which, as calculated by Equation 604, is in direct proportion to absolute temperature. Since level at node 124 is equal to base-emitter junction voltage of transistor 111, 1123 is expressed as

$${I}_{123} = \frac{{V}_{be 1}}{{R}_{123}} \qquad ( 606 )$$

wherein I123 is the current going through resistor 123, Vbe1 is base-emitter junction voltage of transistor 111, and R123 is the resistance of resistor 123. Since Vbe1 is a negative temperature coefficient, current I123 is also negative temperature coefficient.

Current going through transistor 116 is the sum of currents flowing through transistor 120, 121 and 122. The current going through transistor 120, which can be calculated by Equation 606, is negative temperature coefficient. Currents going through transistors 121 and 122, as calculated by Equation 606, are equal, which is positive temperature coefficient. Transistors 116 and 117 build up a 1:1 current mirror, and currents flowing through transistors 116 and 117 are equal. Therefore,

I_{fwd}=I₁₂₃+2I (607)

According to Equations 604, 606 and Equation 607, we have

$${I}_{ref} = \frac{{V}_{be 1}}{{R}_{123}} + \frac{2 KT}{{qR}_{1}} ln M \qquad ( 608 )$$

wherein parameters are the same as described before. The first term on the right of Equation 608 is negative temperature coefficient, which can be adjusted by tuning R123. The second term on the right of Equation 608 is positive temperature coefficient, which can be adjusted by tuning parameters R1 and M. By choosing values for R123, R1 and M, a zero temperature coefficient can be obtained for Iref in certain atmospheric temperature.

Said current reference circuit achieves zero temperature coefficient in certain atmospheric temperature, however, its circuit is much complicated (including operational amplifier), and it occupies large chip area. Besides, the reference current of circuit is subject to effects of offset voltage of the operational amplifier.

FIG. 4 illustrates a conventional current reference circuit comprising bipolar transistors (BJT) 312, 313, 314, 315, MOS transistors 316, 317, 318, 319, 320, 321 and resistor 311. MOS transistors 316 and 318, 317 and 319 build up a 1:1 cascode current mirror. The MOS transistors 320 and 321, 319 and 317 build up a cascode proportional current mirror, in which current ratio is realized by designing transistor sizes, usually 1:1 current mirror. Iref is the desired reference current. On condition of veracity, effects of base current of bipolar transistor are neglected (in fact, current amplification factor of bipolar transistors is too high, about the order of hundred times, to affect the accuracy). Since voltage drops of each branch from node 322 to ground are equal, the following could be derived:

V_{be4}+V_{be2}+IR=V_{be5}+V_{be3} (609

wherein Vbe4, Vbe2, Vbe5, and Vbe3 are base-emitter junction voltages of bipolar transistors 314, 312, 315 and 313, respectively, I is the current going through resistor 311, and R is the resistance of resistor 311. By substituting current-voltage expression of bipolar transistor to Equation 609, the following expression is derived:

$${V}_{t} ln \frac{I}{{I}_{s 4}} + {V}_{t} ln \frac{I}{{I}_{s 2}} + IR = {V}_{t} ln \frac{I}{{I}_{s 5}} + {V}_{t} ln \frac{I}{{I}_{s 3}} \qquad ( 610 )$$

wherein Is4, Is2, Is5, and Is3 are device constants of transistors 314, 312, 315 and 313, respectively, which are directly proportional to an emitter size of transistors. Other parameters are as mentioned above. According to Equation 610, the following expression is obtained:

$$I = \frac{{V}_{t}}{R} ln \frac{{I}_{s 4} {I}_{s 2}}{{I}_{s 5} {I}_{s 3}} \qquad ( 611 )$$

By substituting expression of Vt to Equation 611, we obtain:

$$I = \frac{KT}{qR} ln \frac{{I}_{s 4} {I}_{s 2}}{{I}_{s 5} {I}_{s 3}} \qquad ( 612 )$$

wherein parameters have the same implication as described before. Due to current mirror:

$${I}_{ref} = I = \frac{KT}{qR} ln \frac{{I}_{s 4} {I}_{s 2}}{{I}_{s 5} {I}_{s 3}} \qquad ( 613 )$$

wherein Iref is a current in direct proportion to absolute temperature.

The foregoing current reference circuit features simple structure and small chip size. But the reference current it generates is varying with temperature, which can not meet requirements of high resolution A/D and D/A convertors for highly stable reference current. Another disadvantage of the circuit is possible latchup at power on, in addition, the startup circuit is hard to design.

Therefore, there exists a pressing need for a current reference circuit that can provide stable reference current for other circuit blocks in integrated circuits.

### BRIEF SUMMARY OF THE INVENTION

Accordingly, an object of the invention is to provide a stable reference current for other circuit blocks in an IC. The invention solves problems associated with complication of the circuit, unstableness of reference signals and circuit startup. It is preferably applicable for high performance A/D and D/A converters, where requirements for reference signals are very strict.

The foregoing objects of the invention are accomplished as follows:

The invention provides a BiCMOS current reference circuit comprising a startup circuit, a reference core circuit and a reference current output circuit, wherein the startup circuit, for starting up the reference core circuit at power on; the reference core circuit, for generating a reference current with zero temperature coefficient at atmospheric temperature by cancelling negative temperature coefficient current with positive temperature coefficient current; the reference current output circuit, for outputting the reference current generated from the reference core circuit in proportion.

Then, the reference core includes a first reference core transistor, a second reference core transistor, a third reference core transistor, a fourth reference core transistor, a fifth reference core transistor, a first resistor, a second resistor and a current mirror circuit. The collector of the first reference core transistor is connected to the emitter of the third reference core transistor. The collector of the second reference core transistor is connected to the emitter of the fourth reference core transistor. The emitter of the first reference core transistor is grounded via the second resistor. The base of first reference core transistor is connected to the collector of the second reference core transistor. The base of the second reference core transistor is connected to the collector of the first reference core transistor. Bases of the third, fourth and fifth reference core transistors are connected. The collector of the fifth reference core transistor is connected to the collector of the fourth reference core transistor. The emitter of the fifth reference core transistor is grounded via the first resistor. The base of the first reference core transistor is connected to its collector and then to the output end of startup circuit. The said current mirror circuit is set between the collectors of the third and fourth reference core transistors. The output end of the current mirror circuit is connected to the reference current output circuit.

Then, the current mirror circuit contains at least a pair of cascode current mirror circuits, which consists of the first current mirror transistor and the second current mirror transistor. The gates of the said first transistor and the second transistor are connected, which is then connected to the drain of the second transistor. The said second transistor and the source of the second transistor are connected to power supply, respectively. The drain of the second transistor is connected to the reference current output circuit.

Then, the startup circuit includes a first startup transistor, a second startup transistor, a first startup resistor, a second startup resistor and a third startup resistor. The first, second and third startup resistors are connected in series between power supply and ground. The base of the second startup transistor is connected to a common connector of the second and third startup resistors. The emitter of the second startup transistor is grounded. The collector of the second startup transistor is connected to the base of the first startup transistor. The base of the first startup transistor is connected to a common connector of the first and second startup resistors. The collector of the first startup transistor is connected to power supply. The emitter of the first startup transistor is connected to the bases of the third and fourth reference core transistors.

Then, the reference current output circuit has at least an output unit, which is connected to the output end of the current mirror circuit of the said reference core circuit.

Then, the output unit includes a first output transistor and a second output transistor. The source of the first output transistor is connected to the drain of the second output transistor. The gates of the first and second output transistors are connected to corresponding output ends of current mirror circuits, respectively. The drain of the first output transistor is connected to power supply. The source of the second output transistor is the output end of reference current.

Then, the first and second startup transistors are PMOS transistors. The first and second current mirror transistors are PMOS transistors. The first and fifth reference core transistors are N-type Bipolar transistors.

Then, the node level at the base of the first startup transistor is 2.5 times base-emitter junction voltage of the first startup transistor.

The invention has following advantages. Based on conventional current reference circuit, which is in direct proportion to absolute temperature (PTAT), a current in reverse proportion to absolute temperature is added to cancel positive temperature coefficient of PTAT current. By adjusting proportion of the two currents, a current reference with zero temperature coefficient at atmospheric temperature is obtained. Compared with the conventional voltage reference circuit, the present invention uses current conveying technique, so the circuit is not affected by DC voltage drops of the power supply network, and it features low transmission loss, good matching, excellent temperature stability, small chip size and auto-startup at power-on.

The invention provides a current reference circuit, which solves problems associated with complication of the circuit, unstableness of reference signals and circuit startup. It is preferably applicable for high performance A/D and D/A converters, where requirements for reference signals are very strict.

### BRIEF DESCRIPTION OF THE DRAWINGS

FIG. 1 is a conventional voltage reference circuit.

FIG. 2 is a conventional current reference circuit.

FIG. 3 is a conventional current reference circuit.

FIG. 4 is a conventional current reference circuit.

FIG. 5 is preferred embodiment 1 of the invention.

FIG. 6 is preferred embodiment 2 of the invention.

FIG. 7 is preferred embodiment 3 of the invention.

FIG. 8 is preferred embodiment 4 of the invention.

FIG. 9 is preferred embodiment 5 of the invention.

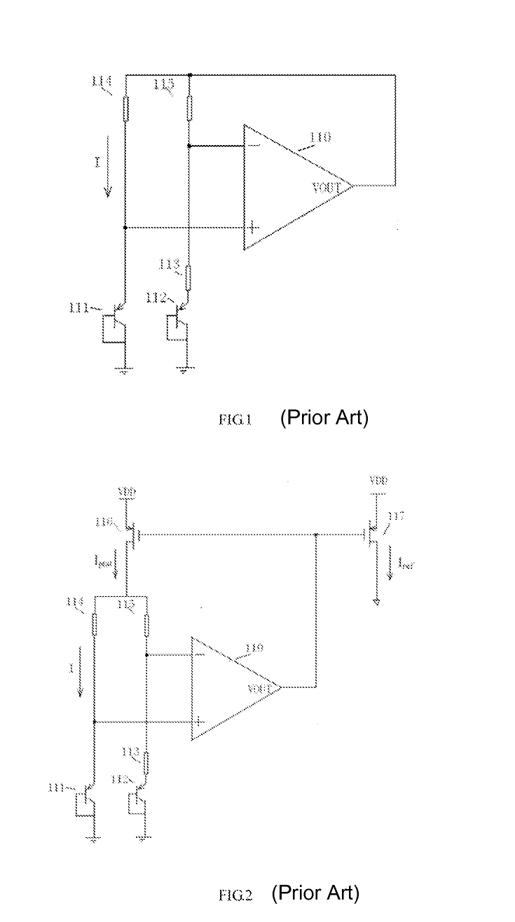

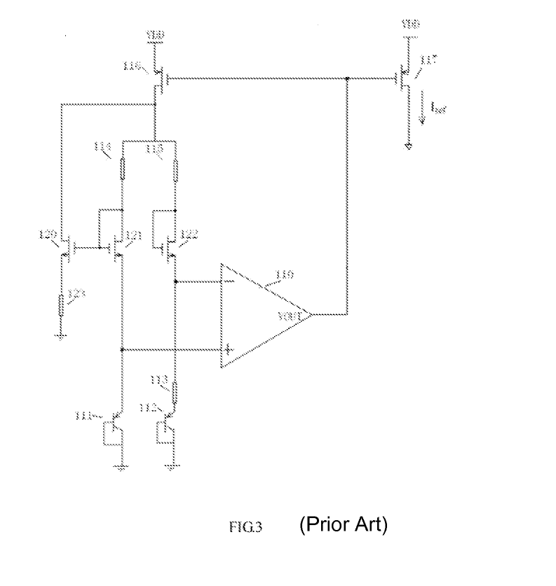

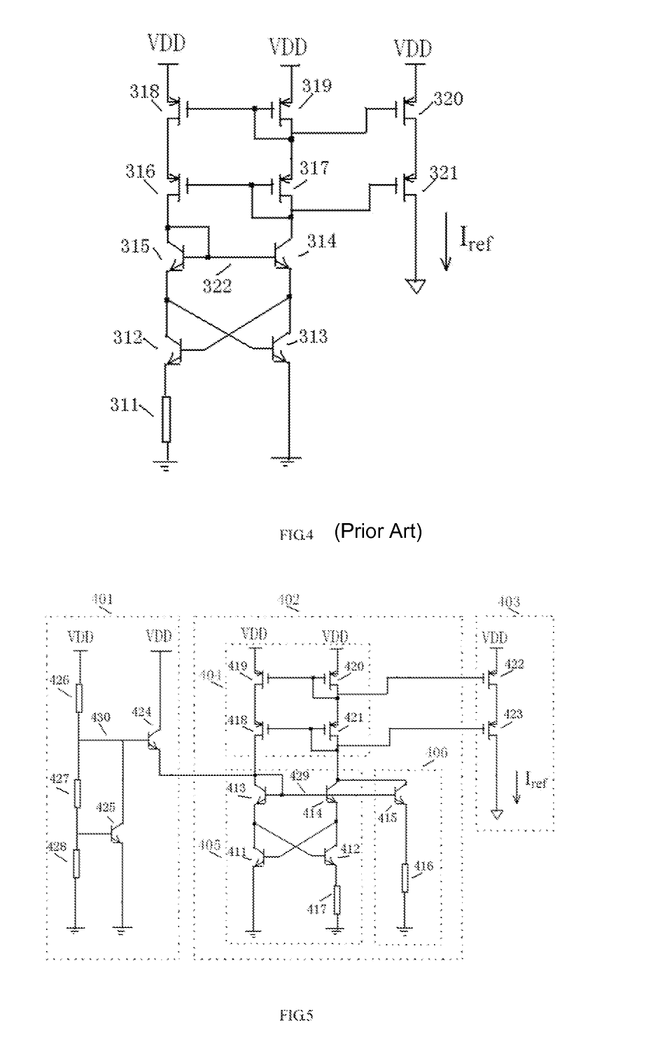

### DETAILED DESCRIPTION OF THE INVENTION

Hereinafter, the preferred embodiments of the present invention will be described with the accompanying drawings. It should be understood that the following embodiments are provided just for describing the invention, instead of limiting the property protection scope of the invention.

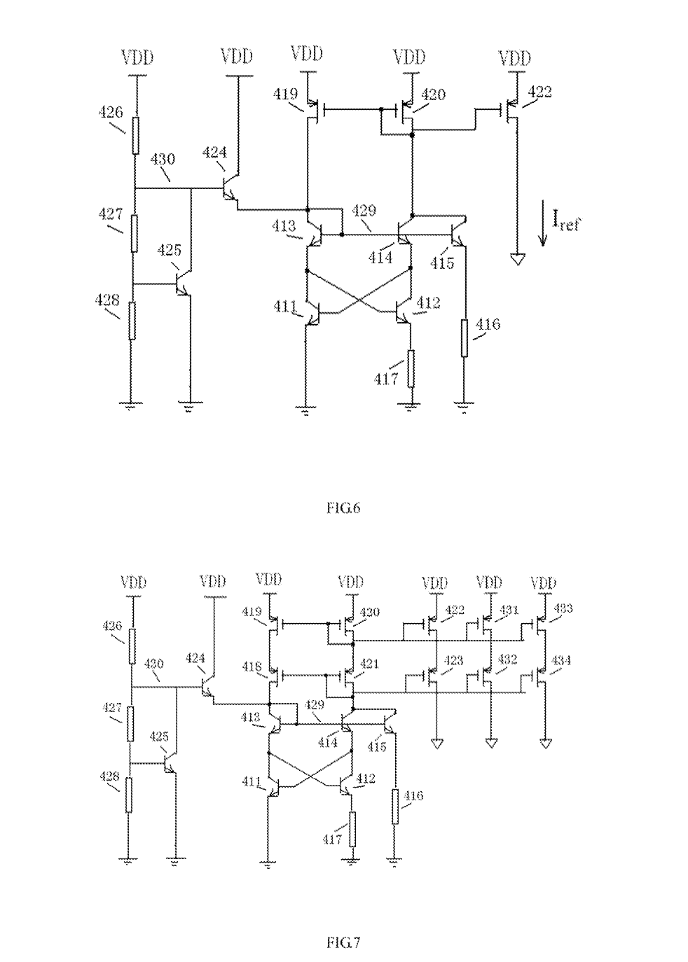

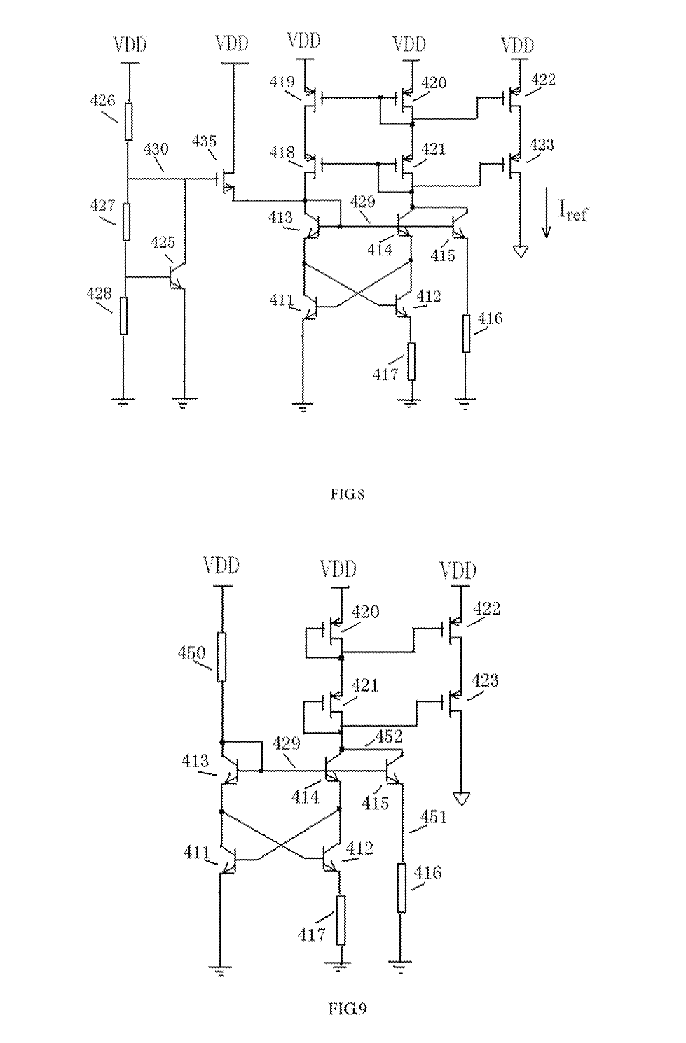

FIG. 5, FIG. 6, FIG. 7, FIG. 8 and FIG. 9 are preferred embodiments 1, 2, 3, 4 and 5 of the invention, respectively. As shown in these figures, the BiCMOS current reference circuit presented in the invention includes a startup circuit, a reference core circuit, and a reference current output circuit. The startup circuit starts up the reference core circuit at power on. The reference core circuit generates reference current with zero temperature coefficient at atmospheric temperature by cancelling positive temperature coefficient current with negative temperature coefficient current. The reference core circuit is a key circuit of the invention for generating reference current independent of temperature and power supply. As it is likely to happen that the reference core circuit does not work at power on, the startup circuit is used to start the reference circuit in that case.

The reference current output circuit outputs the reference current generated by the reference core circuit in proportion. The current is adjustable depending on the number of circuit cells that need reference current. The reference current output circuit, which conveys stable reference current proportionably to other circuit cells in the IC, provides current reference for them.

The reference core includes a first reference core transistor, a second reference core transistor, a third reference core transistor, a fourth reference core transistor, a fifth reference core transistor, a first resistor, a second resistor and a current mirror circuit. The collector of the first reference core transistor is connected to the emitter of the third reference core transistor. The collector of the second reference core transistor is connected to the emitter of the fourth reference core transistor. The emitter of the first reference core transistor is grounded through the second resistor. The base of the first reference core transistor is connected to the collector of the second reference core transistor. The base of the second reference core transistor is connected to the collector of the first reference core transistor. Bases of the third, fourth and fifth reference core transistor are connected together. The collector of the fifth reference core transistor is connected to that of the fourth reference core transistor. The emitter of the fifth reference core transistor is grounded through the first resistor. The base of the first reference core transistor is connected to its collector and then to the output end of the startup circuit. The said current mirror circuit is placed between collectors of the third and fourth reference core transistors. The output end of the current mirror circuit is connected to the reference current output circuit. The current mirror circuit has at least a pair of cascode current mirror circuit, which includes the first current mirror transistor and the second current mirror transistor. The first transistor is connected to the gate of the second transistor and then to the drain of the second transistor. The second transistor and its source are separately connected to power supply. The drain of the second transistor is connected to the reference current output circuit.

The startup circuit includes the first startup transistor, the second startup transistor, the first startup resistor, the second startup resistor, and the third startup resistor. The first, second and third startup resistors are connected in series between power supply and ground. The base of the second startup transistor is connected to a common connector of the second and third startup resistors. The emitter of the second startup transistor is grounded. The collector of the second startup transistor is connected to the base of the first startup transistor. The base of the first startup transistor is connected to a common connector of the first and second startup resistor. The collector of the first startup transistor is connected to the power supply. The emitter of the first startup transistor is connected to bases of the third and fourth reference core transistors. The reference current output circuit has at least one output unit, which is connected to the output end of the current mirror circuit in the reference core circuit. Said output unit includes the first output transistor and the second output transistor. The source of the first output transistor is connected to the drain of the second output transistor. Gates of the first and second output transistors are connected to corresponding output ends of the current mirror circuit, respectively. The drain of the first output transistor is connected to power supply. The source of the second output transistor is the output end of reference current.

The first and second startup transistors, as well as the first and second current mirror transistors, are PMOS transistors. The first and fifth reference core transistors are N-type bipolar transistors. The node level at base of the first startup transistor is 2.5 times base-emitter junction voltage of the first startup transistor.

FIG. 5 shows preferred embodiment 1 of the invention. The invention is presented in details with the accompanying preferred embodiment 1. FIG. 5 shows a circuit including a reference core 402, a startup circuit 401 and a reference current output circuit 403. The reference core 402 includes a current mirror circuit 404, a positive temperature coefficient current generator 405 and a negative temperature coefficient current generator 406. The current mirror circuit 404 consists of PMOS transistors 418, 419, 420 and 421, which forms a pair of 1:1 cascode current mirror, so that two branches of currents, assumable current I, flowing through the 1:1 cascode current mirror are the same. The positive temperature coefficient current generator 405 include bipolar transistors 411, 412, 413 and 414, and a resistor 417. The negative temperature coefficient current generator 406 includes a bipolar transistor 415 and a resistor 416. The startup circuit 401 includes bipolar transistors 424, 425, resistors 426, 427 and 428. The reference current output circuit 403 includes PMOS transistors 422 and 423. The PMOS transistors 422, and 423, 420 and 421 build up a proportional current mirror, of which the current ratio can be set as desired. Current Iref from the drain of PMOS transistor is the desired reference current. The following analysis neglects effects of bipolar transistor's base current, without loss of accuracy.

Since voltage drops of each branch from node 429 to ground are equal, the following expression can be derived:

I₂R+V_{be2}+V_{be3}=V_{be4}+V_{be1} (614)

wherein R is the resistance of resistor 417, and I2 is the current through resistor 417, Vbe2, Vbe3, Vbe4 and Vbe1 are base-emitter junction voltages of transistors 412, 413, 414, and 411, respectively. Substituting voltage-current expression of bipolar transistor to Equation 614, we have:

$${I}_{2} R + {V}_{t} ln \frac{{I}_{2}}{{I}_{s 2}} + {V}_{t} ln \frac{{I}_{1}}{{I}_{s 3}} = {V}_{t} ln \frac{{I}_{2}}{{I}_{s 4}} + {V}_{t} ln \frac{{I}_{1}}{{I}_{s 1}} \qquad ( 615 )$$

wherein I1 is the current through branch circuit in which bipolar transistor 411 is, Vt is a physical constant, which is about 0.026V at atmospheric temperature, directly proportional to absolute temperature, Is1, Is2, Is3, and Is4 are device constants for bipolar transistors 411, 412, 413 and 414, which are in direct proportion to their emitter junction sizes. Other parameters are as described before. Sorting out Equation 615, the following is obtained:

$${I}_{2} = \frac{{V}_{t}}{R} ln \frac{{I}_{s 2} {I}_{s 3}}{{I}_{s 4} {I}_{s 1}} \qquad ( 616 )$$

Substituting expression of Vt to Equation 616, we have:

$${I}_{2} = \frac{KT}{qR} ln \frac{{I}_{s 2} {I}_{s 3}}{{I}_{s 4} {I}_{s 1}} \qquad ( 617 )$$

wherein K is Boltzmann constant, T is absolute temperature, q is the quantity of electric charge, and other parameters are as mentioned above. Equation 617 shows current I2 is in direct proportion to absolute temperature.

Look at the branch where resistor 416 and transistor 415 are, assuming that current through this branch is I3. Similarly, as voltage drops of each branch from node 429 to ground are equal, we have:

I₃R₁+V_{be5}=V_{be4}+V_{be1} (618

wherein R1 is the resistance of resistor 416, Vbe5 is the base-emitter voltage of bipolar transistor 415, and other parameters are as described before. Since Vbe5 is approximately equal to Vbe4, Equation 618 can be reduced as:

$${I}_{3} = \frac{{V}_{be 1}}{{R}_{1}} \qquad ( 619 )$$

Since Vbe1 is the negative temperature coefficient, I3 is also the negative temperature coefficient.

As current through the branch where transistor 421 is equal to the sum of currents going through branches where transistors 414 and 415 are, so:

I=I₃+I₂ (620)

wherein I is the current through the branch where transistor 421 is. According to Equations 617, 619 and Equation 620, the following is derived:

$$I = \frac{{V}_{be 1}}{{R}_{1}} + \frac{KT}{qR} ln \frac{{I}_{s 2} {I}_{s 3}}{{I}_{s 4} {I}_{s 1}} \qquad ( 621 )$$

wherein the first term on the right is negative temperature coefficient, and the second term on the right is positive temperature coefficient. To achieve better matching, emitter sizes of bipolar transistors 414 and 413 are generally designed to be equal, and emitter size of bipolar transistor 412 is M times that of bipolar transistor 411. Thus, Equation 621 is reduced to:

$$I = \frac{{V}_{be 1}}{{R}_{1}} + \frac{KT}{qR} ln M \qquad ( 622 )$$

The negative temperature coefficient can be tuned by adjusting resistance of R1, and the positive temperature coefficient can be tuned by adjusting resistance R and ratio M. Current I with zero temperature coefficient at a certain temperature can be realized by choosing values of R1, R and M.

Described above is the operational principle of the current reference core 402. However, with only core circuit, the current reference does not work, for the reference core circuit will be latched up at power on, namely, no currents flowing through each branch. To prevent from such case, startup circuit 401 is designed to make reference core circuit work.

The startup circuit 401 consists of resistors 426, 427, 428, and bipolar transistors 424, 425. Voltage level at node 430 is designed to be 2.5 Vbe, where Vbe is the base-emitter junction voltage of bipolar transistor. This can be achieved by tuning resistance value of resistors 427 and 428, i.e., adjusting resistance value of resistor 427 to 1.5 times that of resistor 428. The startup procedure of the reference core circuit at power on is related as follows.

When the power is on, no currents flowing through branches of the reference core circuit and resistor 416. Voltage at node 429 is below Vbe, when transistor 424 injects current into node 429. First, a current passes through resistor 416 is to set up 0.5 Vbe voltage. And then, it goes through PMOS transistors 420 and 421. Due to current mirror, PMOS transistors 419 and 418 also have currents going through, and voltage level at node 429 rises. So, currents flowing through transistors 420 and 421 further rises, which makes currents through transistors 419 and 418 keep increasing, and voltage level at node 429 still rises. Finally, the current reference core circuit enters into normal operation mode, when levels at nodes 429 and 430 are 2 Vbe and 2.5 Vbe, respectively. And now, the base-emitter voltage of transistor 424 is only 0.5 Vbe, and transistor 424 is turned off, without any effect on the reference core circuit.

The reference current output circuit 403 conveys stable reference current proportionably to other circuit blocks in the IC. It should be understood that the reference current output is adjustable depending on the number of desired reference currents, which should not be regarded as limiting the property protection scope of the invention.

The foregoing embodiments are preferred embodiments. Bearing the essence and concept of the present invention, various changes and redesigns made to the embodiment are also covered by claims of the present invention. Provided as follows are some other possible embodiments, which do not limit technical approaches in the present invention.

### Embodiment 2

FIG. 6 shows another embodiment of the invention. In this embodiment, the cascode current mirror consisting of PMOS transistors 419 and 418, 420 and 421, 422 and 423 in the preferred embodiment 1 is modified as a simple current mirror comprising PMOS transistors 419, 420 and 422. The modification simplifies the circuit, but the performance of current matching will be degraded. This embodiment can also achieve the goal of the present invention.

### Embodiment 3

FIG. 7 shows another embodiment of the invention, which has additional numbers of output current based on the preferred embodiment 1 to provide reference currents for more circuit cells.

### Embodiment 4

FIG. 8 shows another embodiment of the invention, which modifies the startup circuit in preferred embodiment 1, wherein the bipolar transistor 424 is replaced by a NMOS transistor 435. This alteration can still reach the goal of the startup circuit.

### Embodiment 5

FIG. 9 shows another embodiment of the invention. By using a resistor 450 for startup of the reference circuit, this embodiment has a simpler structure. The startup procedure is as follows: when the circuit is powered on, if no current flows in each branch, level at node 429 is supply voltage VDD, and level at node 451 is zero, therefore, base-emitter junction voltage of transistor 415 is VDD. If no current flows through transistor 415, level at node 452 is zero, when current passes through transistors 420 and 421, which starts two branches where resistors 416 and 417 are, and finally start the entire current reference circuit.

The foregoing preferred embodiments are provided to describe, not to limit, technical approaches in the present invention. Obviously, bearing the essence and concept of the present invention, technologists in this field can make various changes and redesigns to the present invention. It should be understood that those changes and redesigns are also covered by claims of the present invention, if they are with the same purpose and within the same scope of the present invention.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A Bipolar Complementary Metal Oxide Semiconductor (BiCMOS) current reference circuit, comprising a startup circuit, a reference core circuit, and a reference current output circuit, wherein:
the startup circuit, for starting the reference core circuit at power on;
the reference core circuit, for generating reference current with zero temperature coefficient at room temperature by canceling positive temperature coefficient current with negative temperature coefficient current; and
the reference current output circuit, for proportionably outputting reference current generated by the reference core circuit.

2. The BiCMOS current reference circuit of claim 1, wherein the reference core circuit comprises a first reference core transistor, a second reference core transistor, a third reference core transistor, a fourth reference core transistor, a fifth reference core transistor, a first resistor, a second resistor, and a current mirror circuit, a collector of the first reference core transistor is connected to an emitter of the third reference core transistor, a collector of the second reference core transistor is connected to an emitter of the fourth reference core transistor, and an emitter of the first reference core transistor is grounded through the second resistor, a base of the first reference core transistor is connected to a collector of the second reference core transistor, a base of the second reference core transistor is connected to a collector of the first reference core transistor, bases of the third, fourth and fifth reference core transistors are connected together, a collector of the fifth reference core transistor is connected to a collector of the fourth reference core transistor, an emitter of the fifth reference core transistor is grounded through the first resistor, a base of the first reference core transistor is connected to a collector of the first reference core transistor, and then to the output end of the startup circuit, the current mirror circuit is designed between collectors of the third and fourth reference core transistors, and the output end of the current mirror circuit is connected to the reference current output circuit.

3. The BiCMOS current reference circuit of claim 2, wherein the current mirror circuit comprises at least a pair of cascode current mirror circuit, which consist of a first current mirror transistor and a second current image transistor, gates of the first current image transistor and the second current image transistor are connected to a drain of the second current image transistor, sources of the first and second current image transistor are connected to the power supply, a drain of the second transistor is connected to the reference current output circuit.

4. The BiCMOS current reference circuit of claim 1, wherein the startup circuit comprises a first startup transistor, a second startup transistor, a first startup resistor, a second startup resistor, and a third startup resistor, the first, second and third startup resistors are connected in series between the power supply and ground, a base of the second startup transistor is connected to a common connector of the second and third startup resistors, an emitter of the second startup transistor is grounded, a collector of the second startup transistor is connected to a base of the first startup transistor, a base of first startup transistor is connected to a common connector of the first and second startup resistors, a collector of the first startup transistor is connected to the power supply, an emitter of the first startup transistor is connected to the bases of the third and fourth reference core transistors.

5. The BiCMOS current reference circuit of claim 1, wherein the reference current output circuit comprises at least one output unit, which is connected to the output end of the current mirror circuit of the reference core circuit.

6. The BiCMOS current reference circuit of claim 5, wherein the output unit comprises a first output transistor and a second output transistor, a source of the first output transistor is connected to a drain of the second output transistor, gates of the first and second output transistors are connected to output ends of the corresponding current mirror circuits, respectively, a drain of the first output transistor is connected to the power supply, and a source of the second output transistor is the output end of the reference current.

7. The BiCMOS current reference circuit of claim 6, wherein the first and second startup transistors are PMOS transistors, the first and second current mirror transistors are PMOS transistors, and the first to fifth reference core transistors are N-type bipolar transistors.

8. The BiCMOS current reference circuit of claim 7, wherein a base node potential of the first startup transistor is 2.5 times base-emitter junction voltage of the first startup transistor.
